(19) United States
(12) Patent Application Publication
(10) Pub. No.: US 2025/0316508 A1
(43) Pub. Date: Oct. 9, 2025

(54) SUBSTRATE PROCESSING APPARATUS

(71) Applicant: SAMSUNG ELECTRONICS CO., LTD., Suwon-si (KR)

(72) Inventors: SUHWAN HWANG, Suwon-si (KR); Eunhee KOO, Suwon-si (KR); JUN RAE KIM, Suwon-si (KR); Jihoon KIM, Suwon-si (KR); Taehyeon PARK, Suwon-si (KR); TAEMIN EARMME, Suwon-si (KR); Seoungho OH, Suwon-si (KR); Hyang-rok LEE, Suwon-si (KR); YIHWAN KIM, Suwon-si (KR); CHUNHYUNG CHUNG, Suwon-si (KR)

(73) Assignee: SAMSUNG ELECTRONICS CO., LTD., Suwon-si (KR)

(21) Appl. No.: 19/011,161

(22) Filed: Jan. 6, 2025

(30) Foreign Application Priority Data
Apr. 8, 2024 (KR) 10-2024-0047562

(51) Int. Cl. H01L 21/67; B23K 26/08; B23K 26/12; B23K 26/70; B23K 103/00

(52) U.S. Cl. CPC H01L 21/67115; B23K 26/0861; B23K 26/127; B23K 26/702; B23K 2103/56

(57) ABSTRACT

There is provided a substrate processing apparatus including a chamber including a support portion for supporting a substrate in an internal space and having opening at a one side of the chamber, a window portion provided at the opening, and a laser irradiation device that irradiates the laser beam to the substrate through the window portion. The window portion includes a first window and a second window spaced apart by a gap.

### CROSS-REFERENCE TO RELATED APPLICATION

This application is based on and claims priority to and the benefit of Korean Patent Application No. 10-2024-0047562, filed in the Korean Intellectual Property Office on Apr. 8, 2024, the entire contents of which are incorporated herein by reference.

### BACKGROUND

### 1. Field

The disclosure relates to a substrate processing apparatus.

### 2. Description of the Related Art

In the semiconductor device manufacturing process, after ions are implanted into a wafer, annealing is performed to remove deformation caused by ion implantation or to activate the implanted ions.

The annealing process using a laser beam anneals the wafer in a chamber by transmitting the laser beam through a window of the chamber.

However, a temperature change region occurs between the window and a laser irradiation head due to a heater in the chamber. In this temperature change region, a refractive index of the laser beam changes, which may cause errors in a processing region on the wafer by the laser beam.

Additionally, for wafer processing using a laser beam, the chamber may be moved on a stage. However, due to movement of the chamber, shaking may occur in the wafer within the chamber. In particular, in a case in which a center of gravity is biased to a side due to various structures attached to the outside of the chamber, shaking may become more severe. In such a case in which wafer shaking occurs, errors may occur in the processing region on the wafer caused by the laser beam.

### SUMMARY

An aspect of the disclosure attempts to provide a substrate processing apparatus capable of increasing precision of a processing position by a laser beam by minimizing a region where a refractive index of the laser beam changes.

In addition, an aspect of the disclosure attempts to provide a substrate processing apparatus capable of increasing precision of a processing position by a laser beam by minimizing shaking of a substrate in a chamber.

According to an aspect of the disclosure, there is provided a substrate processing apparatus including: a chamber including: a support portion configured to support a substrate in an internal space of the chamber, and an opening at a first side of the chamber; a window portion provided at the opening, the window portion including a first window and a second window spaced apart from each other in a first direction; and a laser irradiation device configured to irradiate a laser beam to the substrate through the window portion.

According to another aspect of the disclosure, there is provided a substrate processing apparatus including: a chamber including: a support portion configured to support a substrate in an internal space of the chamber, and an opening at a first side of the chamber; a window portion provided at the opening, the window portion including a first window and a second window spaced apart from each other in a first direction; a laser irradiation device configured to irradiate a laser beam to the substrate through the window portion; a weight control module to control a position of a center of gravity of the chamber; and a stage module configured to support the chamber.

According to another aspect of the disclosure, there is provided a substrate processing apparatus including: a chamber including: a support portion configured to support a substrate in an internal space, and an opening at a first side of the chamber; a window portion provided at the opening, the window portion including a first window and a second window spaced apart from each other in a first direction; a support portion in the chamber, the support portion configured to support the substrate; a laser irradiation device configured to irradiate a laser beam to the substrate through the window portion; a weight control module configured to control a position of a center of gravity of the chamber; and a stage module configured to movably support the chamber, wherein the support portion includes a heater configured to heat the substrate, and wherein the stage module is configured to move the chamber in a second direction perpendicular to the first direction.

According to an embodiment, a window portion of a chamber may minimize heat transfer to an outside of the window portion by including two windows with a sealed space therebetween. Accordingly, a region where a refractive index of a laser beam changes may be minimized.

Additionally, according to an embodiment, shaking of a substrate within a chamber may be minimized when the chamber is moved by adjusting a position of a center of gravity of the chamber to the center of the chamber.

In this way, precision of a processing position may be increased by a laser beam by minimizing a change in a refractive index of a laser beam and minimizing vibration of a substrate.

### BRIEF DESCRIPTION OF DRAWINGS

Embodiments of the disclosure will be more clearly understood from the following detailed description taken in conjunction with the accompanying drawings in which:

FIG. 1 illustrates a perspective view of a substrate processing apparatus according to an embodiment.

FIG. 2 illustrates a plan view of a substrate processing apparatus according to an embodiment.

FIG. 3 illustrates a cross-sectional view showing a chamber in a substrate processing apparatus according to an embodiment.

FIG. 4 illustrates an enlarged view of a region A of FIG. 3.

FIG. 5 illustrates a chamber of a comparative example.

FIG. 6 illustrates a view for describing a region B of FIG. 5.

FIG. 7 illustrates a plan view showing a weight control module in a substrate processing according to an embodiment.

FIGS. 8 and 9 illustrate views for describing various forms of a region C of FIG. 7.

FIGS. 10 and 11 illustrate views for describing a process of adjusting a center of gravity of a chamber in a substrate processing apparatus according to an embodiment.

### DETAILED DESCRIPTION

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

To clearly describe the disclosure, parts that are irrelevant to the description in the drawings are omitted, and like numerals refer to like or similar constituent elements throughout the specification.

Further, since sizes and thicknesses of constituent members shown in the accompanying drawings are arbitrarily given for better understanding and ease of description, the disclosure is not limited to the illustrated sizes and thicknesses.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” means when an object portion is viewed from above, and the phrase “in a cross-sectional view” means when a cross-section taken by vertically cutting an object portion is viewed from the side.

Hereinafter, a substrate processing apparatus according to various embodiments will be described with reference to the drawings.

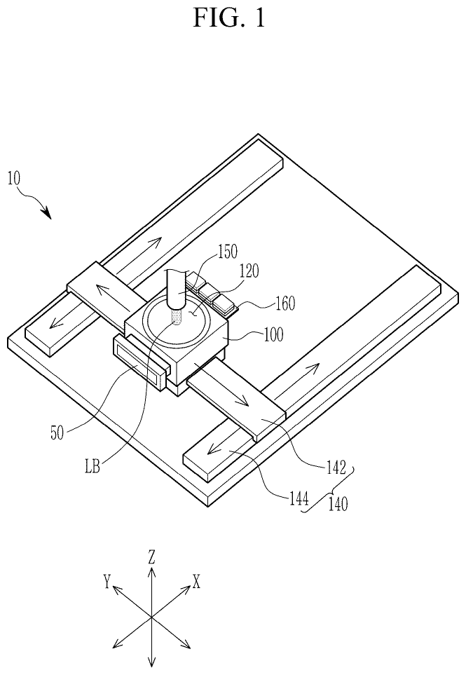

FIG. 1 illustrates a perspective view of a substrate processing apparatus according to an embodiment, and

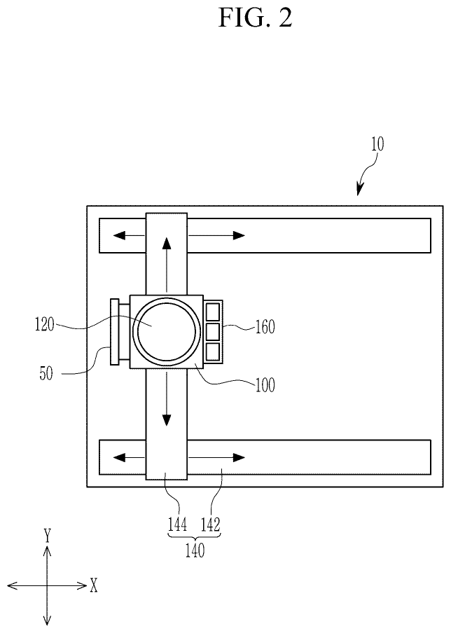

FIG. 2 illustrates a plan view of a substrate processing apparatus according to an embodiment. For convenience of understanding, in FIG. 1, a part (head portion) of a laser irradiation device 150 is illustrated, and in FIG. 2, the laser irradiation device 150 is not illustrated and is omitted.

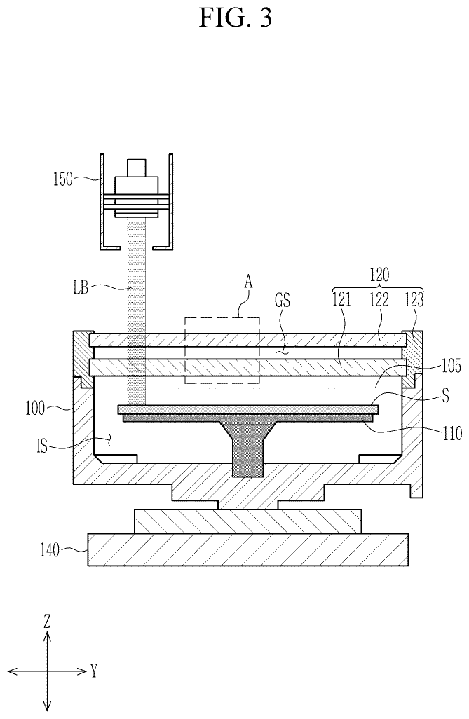

According to an embodiment, the substrate processing apparatus 10 is an apparatus that processes a substrate S by irradiating a laser beam LB to the substrate S (see FIG. 3). According to an embodiment, the substrate processing apparatus 10 may increase precision of a processing position through a laser beam. According to an embodiment, the substrate processing apparatus 10 may be a laser annealing device for activating ions implanted into the substrate S or recrystallizing silicon during a semiconductor manufacturing process. However, the disclosure is not limited thereto, and as such, according to another embodiment, another type of device for processing the substrate S may be included in the substrate processing apparatus 100. For example, any device that processes the substrate S by irradiating a laser beam LB onto the substrate S may be included in the substrate processing apparatus 100. Herein, the substrate S may be a wafer used in semiconductor manufacturing, but the disclosure is not limited thereto. As such, according to another embodiment, the substrate processing apparatus 10 may be an apparatus for processing another type of target material or object. According to another embodiment, the substrate processing apparatus 10 may including a controller for controlling one or more components of the substrate processing apparatus 10. For example, the controller may include a memory storing one or more instructions, and a processor configured to execute the one or more instructions to perform various operations of the substrate processing apparatus 10.

Referring to FIGS. 1 and 2, the substrate processing apparatus 10 includes a chamber 100, a window portion 120, and a laser irradiation device 150. According to an embodiment, the substrate processing apparatus 100 may further include a stage module 140, and a weight control module 160. The stage module 140 may support the chamber 100. For example, the stage module 140 may movable support the chamber 100. The weight control module 160 may be control a position of a center of gravity of the chamber 100. According to an embodiment, the substrate processing apparatus 100 may further include a structure 50 may be provided on a surface of the chamber 100.

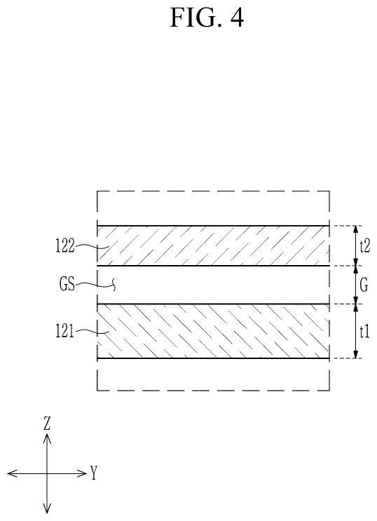

FIG. 3 illustrates a cross-sectional view showing a chamber in a substrate processing apparatus according to an embodiment, and FIG. 4 illustrates an enlarged view of a region A of FIG. 3. In FIG. 3, a structure 50 and the weight control module 160 are not illustrated.

According to an embodiment, the chamber 100 includes an internal space IS in which the substrate S to be processed is positioned to be processed. Referring to FIG. 3, the chamber 100 may include the internal space IS, and may have an opening 105 on a side of the chamber. For example, the opening 105 may be provided on an upper (or a top) side of the chamber.

According to an embodiment, at least a portion of an upper portion of the chamber 100 may have an open structure. According to an embodiment, an entire upper portion of the chamber 100 may have an open structure. According to an embodiment, the opening 105 may be positioned in a direction facing a processing surface of the substrate S.

The internal space IS of the chamber 100 may include a support portion 110 that supports the substrate S. The chamber 100 may have a substantially hexahedral or cylindrical shape. However, the disclosure is not limited thereto, and as such, according to another embodiment, the chamber 100 may have various shapes having an internal space.

The support portion 110 may support the substrate S in the internal space IS of the chamber 100. For example, the support portion 110 may have a support surface in contact with the substrate S. The support surface of the support portion 110 may face the opening 105 of the chamber 100. The substrate S to be processed may be provided on the support surface of the support portion 110. The substrate S may be seated on the support surface of the support portion 110. The support portion 110 may fix the substrate S. For example, the support portion 110 may fix the substrate S in the horizontal direction.

The support portion 110 may be provided with a means for fixing the substrate S. According to an embodiment, the support portion 110 may include an electrostatic chuck that supports the substrate S using electrostatic force. However, the disclosure is not limited thereto, and the support portion 110 may include a vacuum chuck that supports the substrate S using a vacuum pressure, and various types of chucking means for securing the substrate S, such as a clamping structure for securing an edge portion of the substrate S.

The support portion 110 may include a heater that heats the substrate S. The substrate S may be heated by contacting a surface of the substrate S with a support surface (e.g., an upper surface) of the support portion 110. For example, the substrate S may be heated by operating a heater built into the support portion 110. For example, for annealing of the substrate S, the substrate S may be heated to 300° C. or higher by a heater. For example, the heater may be positioned inside the support portion 110. However, the disclosure is not limited thereto, and as such, the substrate S may be heated in another manner according to another embodiment.

In an example case in which the temperature of the internal space IS of the chamber 100 increases based on the heat generated by the heater, the window portion 120 at the opening 105 of the chamber 100 may be heated. For example, the window portion 120 that is blocking or covering the opening 105 of the chamber 100 may be heated based on the temperature in the internal space. As the window portion 120 is heated, a region with non-uniform temperature may occur between the head portion (an end portion from which a laser beam is emitted) of the laser irradiation device 150 and the upper surface of the window portion 120. In regions where the temperature is non-uniform, a refractive index of the laser beam LB may change.

According to an embodiment, the substrate processing apparatus 10 may include the window portion 120 of a special structure, and thus even in a case in which the temperature of the internal space IS of the chamber 100 increases, a change in the refractive index of the laser beam LB may be minimized between the head portion of the laser irradiation device 150 and the upper surface of the window portion 120. In this regard, a detailed configuration of the window portion 120 will be described later.

According to an embodiment, the structure 50 may be provided on a surface of the chamber 100. The structure 50 may be in a form that protrudes from a surface of the chamber 100, and may be in a form that protrudes asymmetrically with respect to the chamber 100. Accordingly, the center of gravity of the chamber 100 may be positioned biased in a direction of the structure 50. For example, in a case in which the chamber 100 is moved, the substrate S inside the chamber 100 may shake, and an error may be generated in the processing position on the substrate S by the laser beam LB.

According to an embodiment, the substrate processing apparatus 10 may control the position of the center of gravity of the chamber 100 through the weight control module 160, which will be described later. The weight control module 160 will be described in detail later.

The structure 50 may be a gate for allowing the substrate S to enter and exit the chamber 100 or a docking structure for connection to another device, but the disclosure is not limited thereto.

The laser irradiation device 150 may be positioned outside the chamber 100. The laser irradiation device 150 may be arranged to face the window portion 120, and may irradiate the laser beam LB to the substrate S within the chamber 100 through the window portion 120. According to an embodiment, the laser irradiation device 150 may include a laser source and an optical system for generating and advancing a laser beam.

For example, an end portion of the laser irradiation device 150 from which the laser beam LB is emitted may be positioned at a distance from the window portion 120. Hereinafter, the end portion of the laser irradiation device 150 referred to as ‘head portion’. For example, the head portion may be positioned at a predetermined distance from the window portion 120. According to an embodiment, a position of the head portion of the laser irradiation device 150 may be fixed. FIGS. 1 and 3 illustrate head portion of the laser irradiation device 150. According to an embodiment, the substrate S may be processed using the laser beam LB while moving the chamber 100. As the chamber 100 is moved by the stage module 140, the processing position on the substrate S by the laser beam LB may be moved.

However, the disclosure is not limited thereto, and as such, according to another embodiment, a position of the head portion of the laser irradiation device 150 may be adjustable. For example, the head portion of the laser irradiation device 150 may be movable in at least one axis direction among X-axis, Y-axis, and Z-axis directions in FIG. 1. In this case, the laser irradiation device 150 and the chamber 100 are each moved individually (or separately), so that the processing position on the substrate S by the laser beam LB may be controlled more precisely.

For example, the laser beam LB radiated from the laser irradiation device 150 passes through window portion 120. For example, the window portion 120 may be provided at the opening 105 of the chamber 100, and the laser beam LB radiated from the laser irradiation device 150 passes through or transmits through the window portion 120. Referring to FIG. 3, the window portion 120 may seal the opening 105 of the chamber 100. The window portion 120 may be positioned to face the substrate S supported on the support portion 110. As illustrated in FIGS. 1 and 2, the window portion 120 may be circular in a plan view. However, the disclosure is not limited thereto, and the window portion 10 may have a polygonal shape in a plan view. According to another embodiment, the window portion 10 may have a shape corresponding to a planar shape of the chamber 100 in a plan view.

Referring to FIGS. 3 and 4, according to an embodiment, the window portion 120 may include a first window 121 and a second window 122. For example, the first window 121 and the second window 122 may be arranged to face each other while being spaced apart by a gap G in a first direction (Z-axis direction). The first window 121 and the second window 122 may be made of a same material. However, the disclosure is not limited thereto, and as such, according to another embodiment, the first window 121 and the second window 122 may be made of different materials.

According to an embodiment, the first window 121 and the second window 122 may be made of a quartz material. However, the materials of the first window 121 and the second window 122 are not limited thereto, and may be made of various materials through which the laser beam LB passes.

A closed space GS may be defined between the first window 121 and the second window 122. The closed space GS may be filled with gas. Heat in the internal space IS of the chamber 100 may be reduced from being emitted to the outside through the window portion 120 by providing the closed space GS. A gas filled in the closed space (GS) may be air. However, the gas filled in the closed space GS is not limited to air, and as such, according to another embodiment, the closed gap may not include air. According to another embodiment, the closed space GS may be include a material that can reduce heat transfer or has a high thermal insulation effect and is made of a material through which the laser beam LB passes. For example, the closed space GS may be include a gas that can reduce the heat transfer or has a high thermal insulation effect and through which the laser beam LB passes.

The first window 121 and the second window 122 may be provided at the opening 105 of the chamber 100. The first window 121 and the second window 122 may seal the opening 105 of the chamber 100. According to an embodiment, a sealing member for sealing may be provided between the first window 121 and the opening 105 and between the second window 122 and the opening 105. Accordingly, the closed space GS between the first window 121 and the second window 122 may be sealed from the outside. Accordingly, heat transfer through the closed space GS may be reduced.

Referring to FIG. 3, the window portion 120 may further include an auxiliary member 123. The auxiliary member 123 may be a part that connects the first window 121 and the second window 122 to the opening 105 of the chamber 100. For example, a first side of the auxiliary member 123 may support the first window 121 and the second window 122 to be sealable. According to an embodiment, a sealing member may be provided between the first side of the auxiliary member 123 and the first window 121, and between the first side of the auxiliary member 123 and the second window 122. According to an embodiment, a second side of the auxiliary member 123 may be coupled to the opening 105 of the chamber 100 through a separate fastening member. However, the disclosure is not limited thereto, and as such, according to another embodiment, the auxiliary member 123 may include a first auxiliary member configured to connect the first window 121 to the opening 105 of the chamber 100 and a second auxiliary member configured to connect the second window 122 to the opening 105 of the chamber 100. For example, the first auxiliary member and the second auxiliary member may be separate from each other.

Referring to FIGS. 3 and 4, the first window 121 and the second window 122 may be arranged side by side. For example, the first window 121 and the second window 122 may be arranged side by side in a direction perpendicular to the first direction (Z-axis direction) in which the first window 121 and the second window 122 face each other. For example, the second window 122 may be provided above the first window 121 in the first direction. The first window 121 may have a first thickness t1 in the first direction (Z-axis direction), and the second window 122 may have a second thickness t2 in the first direction (Z-axis direction). The space GS between the first window 121 and the second window 122 may have a thickness equal to the gap G in the first direction (Z-axis direction).

According to an embodiment, the thickness t1 of the first window 121 and the thickness t2 of the second window 122 may be the same. Herein, the same thickness includes not only the exact same thickness, but also a thickness that is substantially the same because a thickness difference is small. For example, the same thickness may include thickness that is within 10% of t1 and t2. According to another embodiment, the thickness t1 of the first window 121 and the thickness t2 of the second window 122 may be different from each other.

According to an embodiment, a distance of the gap G (thickness of the space GS) may be smaller than the thickness t1 of the first window 121 and the thickness t2 of the second window 122 based on the first direction. In an example case in which the distance of the gap G is greater than the thickness t1 of the first window 121 and the thickness t2 of the second window 122, a volume of the window portion 120 increases. Accordingly, an increase in a volume of the window portion 120 due to presence of the space GS may be minimized by making the distance of the gap G smaller than the thickness t1 of the first window 121 and the thickness t2 of the second window 122.

However, in an example case in which the distance of the gap G is too small, an insulation effect through the space GS between the first window 121 and the second window 122 is reduced. Additionally, it becomes difficult to seal the first window 121 and the second window 122. Accordingly, the distance of the gap G may be maintained at a predetermined distance. For example, the distance of the gap G may be set to be greater than ½ of the thickness t1 of the first window 121 or greater than ½ of the thickness t2 of the second window 122.

Hereinafter, a comparative example with which the insulation effect of the above-described embodiment can be compared will be described with different drawings.

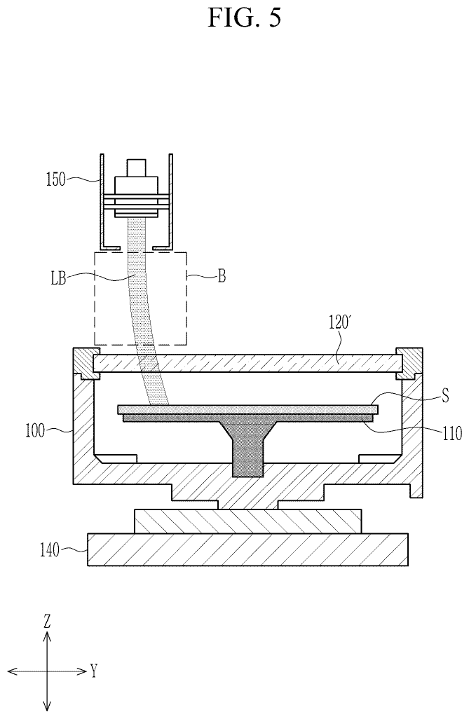

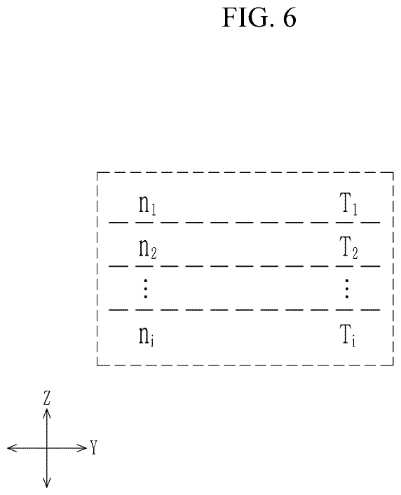

FIG. 5 illustrates a chamber of a comparative example, and FIG. 6 illustrates a view for describing a region B of FIG. 5. The comparative example shown in FIGS. 5 and 6 is a case where the window portion is formed of one window, unlike the embodiment in which the window portion includes two windows.

Referring to FIG. 5, a window portion 120′ of the comparative example includes one window. The substrate S is heated through a heater of the support portion 110 in order to process the substrate S. As the substrate S is heated, the internal space of the chamber 100 is also heated, and heat is transferred outside the chamber 100 through the window portion 120′. Accordingly, referring to FIG. 6, a temperature gradient is generated in a region between a head portion and the window portion 120′ of the laser irradiation device 150.

Referring to FIG. 6, as a region approaches from a region adjacent to the head portion of the laser irradiation device 150 to a region adjacent to the window 120′, a temperature of the region is changed to T₁, T₂, . . . , and Tᵢ (T₁<T₂ . . . <Tᵢ). A refractive index of the laser beam LB is changed to n₁, n₂, . . . , and nᵢ based on temperature changes in each region. This is because the refractive index of the laser beam LB is a function of temperature. That is, the refractive index varies for each region along the vertical direction (Z-axis direction).

According to an embodiment, the temperature may be non-uniform in the horizontal direction (X-axis and Y-axis directions) in a region between the head portion and the window portion 120′ of the laser irradiation device 150. Accordingly, the refractive index in the horizontal direction (X-axis and Y-axis direction) may also be non-uniform. For example, in a case in which the laser beam LB is irradiated toward the window portion 120′ using the laser irradiation device 150, the refractive index of the laser beam LB changes in the vertical and horizontal directions. Accordingly, a problem occurs in which the laser beam LB reaching the substrate S does not accurately reach the position to be processed. That is, since the refractive index of the laser beam LB is non-uniform due to the temperature non-uniformity region, an error in the processing position due to the laser beam LB is generated.

According to an embodiment, the substrate processing apparatus 10 may minimize a problem of refractive index non-uniformity of the laser beam LB that occurs in the above-described comparative example. In more detail, referring to FIG. 3, heat generated in the internal space (IS) of the chamber 100 is transferred outside the chamber 100 through the window portion 120. In this case, heat is transferred outside the chamber 100 by sequentially passing through the first window 121, the closed space GS, and the second window 122. In this structure, heat may not be transferred immediately in the closed space GS, and as such, it may take time for the heat to be transferred outside the chamber 100. Accordingly, thermal equilibrium may be achieved, and the temperature may be made uniform. In addition, in an example case in which the heat transferred to the closed space GS is trapped within the closed space GS for a period of time, the temperature within the closed space GS may be uniform due to gas convection. The period of time may be a predetermined period of time.

Accordingly, in the substrate processing apparatus 10 according to an embodiment, the temperature may be made uniform in the vertical and horizontal directions in a region between the head portion and the window portion 120 of the laser irradiation device 150, and thus the refractive index of the laser beam LB may also be made uniform. As a result, according to an embodiment, the substrate processing apparatus 10 may improve precision of the processing position by the laser beam LB.

According to an embodiment, the stage module 140 is configured to move the chamber 100. The stage module 140 may movably support the chamber 100. The stage module 140 may support the chamber 100 to be movable in a direction perpendicular to the first direction (Z-axis direction). Referring to FIGS. 1 and 2, according to an embodiment, the stage module 140 may support the chamber 100 movably in a second direction (Y-axis direction) and a third direction (X-axis direction) perpendicular to the first direction (Z-axis direction).

Referring to FIG. 2, the stage module 140 may include a first module 142 and a second module 144. The first module 142 and the second module 144 may convert a driving force into linear motion and transmit the driving force, thereby moving the chamber 100 in the second direction (Y-axis direction) and the third direction (X-axis direction), respectively.

The first module 142 may enable the chamber 100 to move in the second direction (Y-axis direction). According to an embodiment, the first module 142 may include a first driver that moves the chamber 100 in the second direction, and a first guide device extending in the second direction. The first driver may include a motor that provides a driving force to move the chamber 100 in the second direction. For example, the motor may include a linear motor. The first guide device may guide a path along which the chamber 100 moves in the second direction. The first guide device may include a rail extending in the second direction. The first guide device may support the chamber 100 or be connected to the chamber 100.

The second module 144 may enable the chamber 100 to move in the third direction (X-axis direction). According to an embodiment, the second module 144 may include a second driver that moves the chamber 100 in the third direction, and a second guide device extending in the third direction. The second driver may include a motor that provides a driving force to move the chamber 100 in the third direction. For example, the motor may include a linear motor. The second guide device may guide a path along which the chamber 100 moves in the third direction. The second guide device may include a rail extending in the third direction. The second guide device may support the chamber 100 or be connected to the chamber 100. However, the disclosure is not limited thereto, and as such, according to another embodiment, the second guide device may support the first guide device or be connected to the first guide device. According to an embodiment, the first module 142 and the second module 144 may be controller by a controller or a processor. For example, the controller may include a memory storing one or more instructions, and a processor configured to execute the one or more instructions to perform various operations of the first module 142 and the second module 144.

The substrate S may be processed with the laser beam LB while moving the chamber 100 by using the above-described stage module 140. However, as described above, due to the structure 50 coupled to the chamber 100, a center of gravity of the chamber 100 may be positioned off to one side from a center of the chamber 100. For example, in a case in which the chamber 100 is moved, particularly when the chamber 100 is accelerated or decelerated, a problem may occur where the substrate S inside the chamber 100 is shaken. For example, in a case in which the chamber 100 is accelerated or decelerated, a problem may occur where the substrate S inside the chamber 100 is shaken. According to an embodiment, the substrate processing apparatus 10 may address and/or solve the above-described problem by including the weight control module 160.

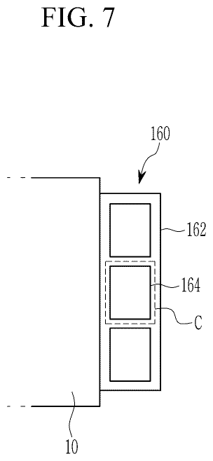

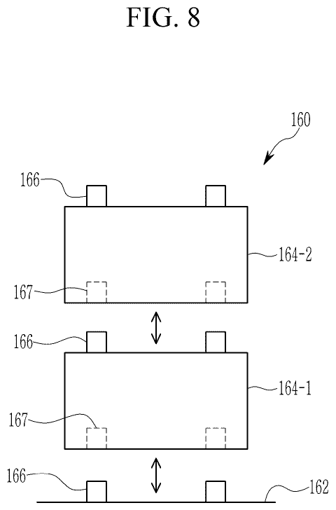

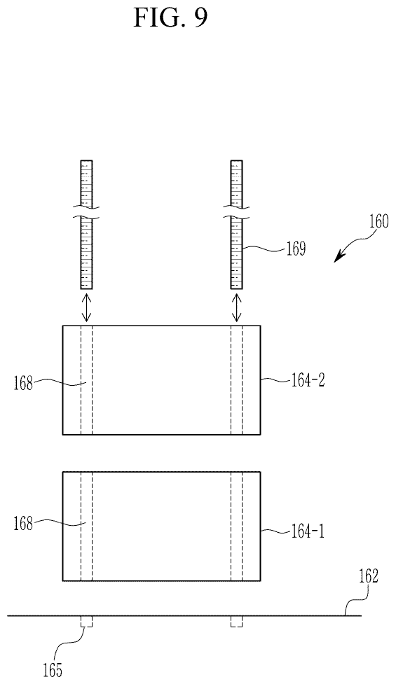

FIG. 7 illustrates a plan view showing a weight control module in a substrate processing according to an embodiment. FIGS. 8 and 9 illustrate views for describing various forms of a region C of FIG. 7. FIGS. 7, 8 and 9 illustrate a simplified configuration for ease of understanding.

Referring to FIGS. 1 and 7, the weight control module 160 may include a platform 162 and a block portion 164. The weight control module 160 may be provided at a first side of the chamber 100 to control the position of the center of gravity of the chamber 100.

For example, the platform 162 may be provided on a first side surface of the chamber 100. According to an embodiment, the platform 162 may be positioned in a region of the chamber 100 in an opposite direction to a region where the structure 50 (see FIGS. 1 and 2) is positioned based on the center of the chamber 100. The platform 162 may be provided on the side surface of the chamber 100 and the structure 50 may be provided at a second side surface of the chamber 100 opposite to the first side surface. The platform 162 may be coupled to the first side surface of chamber 100 through a mechanical method.

The platform 162 may have a flat bottom surface. The platform 162 may have a shape that extends horizontally outward from the first side surface of the chamber 100. In FIG. 7, the platform 162 is illustrated exposed to the outside, but this is simplified for ease of understanding. For example, the platform 162 may be coupled with a separate housing covering the block portion 164. In this case, the housing may include a door structure that allows the block portion 164 to enter and exit.

At least one block portion 164 may be mounted on the platform 162. The platform 162 may have an area where a plurality of block portions 164 may be arranged horizontally. In FIG. 7, three block portions 164 are illustrated arranged in a row on the platform 162, but the disclosure is not limited thereto. As an example, two or more block portions 164 may be arranged in one or more rows on the platform 162. For example, the block portions 164 may be arranged in one or more rows and one or more columns on the platform 162.

The block portion 164 is a structure with weight. The block portion may be made of a metal material, but the disclosure is not limited thereto, and may be made of various materials. The block portion 164 may be mounted on the platform 162. The block portion 164 is detachable from the platform 162. A weight of the block portion 164 is adjustable. The position of the center of gravity of the chamber 100 may be adjusted by attaching and detaching the block portion 164 to the platform 162. However, the disclosure is not limited thereto, and as such, according to another embodiment, the position of the center of gravity of the chamber 100 may be adjusted by adjusting the weight of the block portion 164 mounted on the platform 162.

According to an embodiment, the block portion 164 may include at least one block. The block portion 164 may have a form in which at least one block is stacked. The weight of the block portion 164 may be adjusted by adjusting a number of stacked blocks. The blocks may have a shape of a hexahedron, a quadrangular column, a cylinder, or a plate. However, the shape of the blocks is not limited thereto, and may have various shapes.

According to an embodiment, the block portion 164 may include a first block 164-1 and a second block 164-2. Referring to FIGS. 8 and 9, the first block 164-1 may be mounted on the platform 162. The first block 164-1 may be detachable from the platform 162. The second block 164-2 may be stacked on the first block 164-1. The second block 164-2 may be detachable from the first block 164-1.

The first block 164-1 and the second block 164-2 may have a same structure. However, the disclosure is not limited thereto, and as such, according to another embodiment, the first block 164-1 and the second block 164-2 may have different structures. The first block 164-1 and the second block 164-2 may have a same weight. However, the disclosure is not limited thereto, and as such, according to another embodiment, the first block 164-1 and the second block 164-2 may have different weights.

Although FIGS. 8 and 9 show a block portion 164 in which two blocks are stacked, the disclosure is not limited thereto. As such, according to another embodiment, the block portion 164 may include three or more blocks that can be stacked. The block portion 164 may further include a third block that can be stacked on the second block 164-2, and may further include a fourth block that can be stacked on the third block. The block portion 164 may include two or more blocks that can be stacked.

According to an embodiment, at least one block constituting the block portion 164 may have a protrusion 166 protruded from a first surface of the block portion 164. Additionally, a second surface opposite to the first surface may have a groove 167 having a shape corresponding to the shape of the protrusion 166. Referring to FIG. 8, the protrusion 166 of the first block 164-1 may be combined with the groove 167 of the second block 164-2. For example, the protrusion 166 of the first block 164-1 may be inserted into the groove 167 of the second block 164-2. Accordingly, a plurality of blocks may be stacked on top of each other. According to an embodiment, the protrusion 166 of a shape corresponding to the groove 167 of the block may protrude from the platform 162. Accordingly, first block 164-1 may be combined with the platform 162.

Referring to FIG. 9, according to another embodiment, at least one block constituting the block portion 164 may have a fastening hole 168 penetrating from a first surface to a second surface. A plurality of blocks may be fixed on the platform 162 through a fastening member 169 extending through the fastening hole 168. For example, the first block 164-1 and the second block 164-2 may have fastening holes 168 at a same position. While the second block 164-2 stacked on the first block 164-1, the fastening member 169 may be coupled to the platform 162 by extending through the fastening hole 168 of the first block 164-1 and the fastening hole 168 of the second block 164-2 together. According to an embodiment, the platform 162 may be provided with a coupling portion 165 that can be coupled to the fastening member 169. As an example, the fastening member 169 may have a male thread shape, and the fastening hole 168 and the coupling portion 165 may have a female thread shape corresponding to the fastening member 169.

The position of the center of gravity of the chamber 100 may be adjusted through various types of weight control modules 160 described above. For example, the position of the center of gravity of the chamber 100 may be adjusted by adjusting a weight of the block portion 164 mounted on the platform 162 provided at a one side of the chamber 100. For example, the position of the center of gravity of the chamber 100 may be adjusted by adjusting the number of blocks constituting the block portion 164. For example, the position of the center of gravity of the chamber 100 may be adjusted by attaching and detaching at least one block. Hereinafter, a method of adjusting the position of the center of gravity of the chamber 100 will be described.

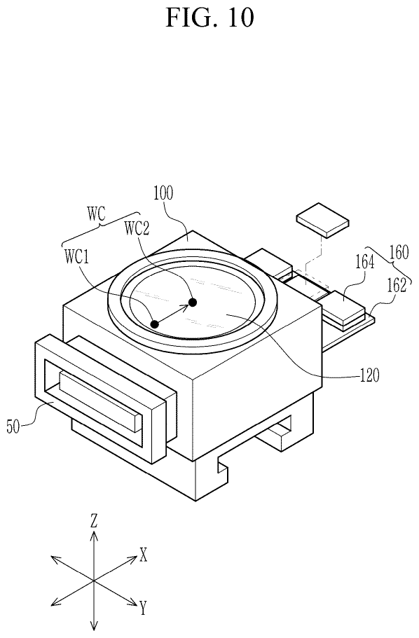

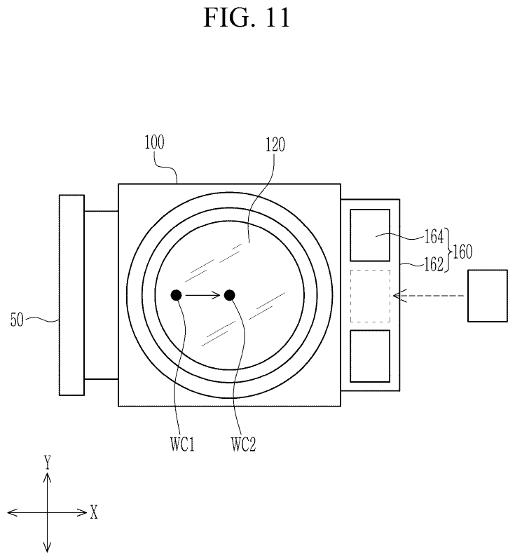

FIGS. 10 and 11 illustrate views for describing a process of adjusting a center of gravity of a chamber in a substrate processing apparatus according to an embodiment.

Referring to FIGS. 10 and 11, a structure 50 may be provided at a one side of the chamber 100. The structure 50 may be a gate for loading the substrate S into the chamber 100 and unloading the substrate S out of the chamber 100. Also, the structure may be a docking structure for connection with another device, but the disclosure is not limited thereto. The structure 50 may have a shape that protrudes to the one side of the chamber 100.

Due to a weight of the structure 50, a center of gravity WC of the chamber 100 may be deviated from a center of the chamber 100 toward the structure 50 (WC1). For example, in a case in which the chamber 100 is moved to process the substrate S through the laser beam LB, the chamber 100 may be shaken. Due to the shaking of the chamber 100, shaking may also occur in the substrate S within the chamber 100. In an example case in which chamber 100 is moved through the stage module 140, shaking may become severe during acceleration and deceleration sections. As a result, errors may occur in a processing region on the substrate S, and overlapping processing regions may occur.

As an example, referring to FIGS. 10 and 11, due to the structure 50, the center of gravity WC may be positioned at a position WC1 deviated in the X-axis direction. In this case, the weight control module 160 may be manipulated to balance the weight of the structure 50. In the weight control module 160, a center block portion of the three block portions 164 may be adjusted. As an example, an additional block may be mounted on the center block portion. In an example case in which an appropriate number of blocks are mounted, the deviated center of gravity WC1 may be moved to a center of the chamber 100 (WC2).

FIGS. 10 and 11 illustrate movement of the center of gravity WC in an axial direction (X-axis direction), but this is only an example. The weight control module 160 may be provided with the block portions 164 arranged in a plurality of rows and a plurality of columns, and the center of gravity WC of the chamber 100 may be easily and precisely adjusted on an XY plane (plane consisting of the X and Y axes).

As such, the substrate processing apparatus 10 according to an embodiment may minimize a change in the refractive index of the laser beam LB passing through a heated area through a configuration of the window portion 120 including a pair of windows with a closed space therebetween. In addition, the substrate processing apparatus 10 according to an embodiment may be configured with the weight control module 160 that adjusts a weight through attachment and detachment of blocks of the chamber 100, so as to minimize shaking of the substrate S due to deviation of the center of gravity of the chamber 100 in an example case in which the chamber 100 moves.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A substrate processing apparatus comprising:
a chamber comprising:
a support portion configured to support a substrate in an internal space of the chamber, and
an opening at a first side of the chamber;
a window portion provided at the opening, the window portion comprising a first window and a second window spaced apart from each other in a first direction; and
a laser irradiation device configured to irradiate a laser beam to the substrate through the window portion.

2. The substrate processing apparatus of claim 1, wherein the window portion is configured to seal the opening,
wherein a closed space is provided between the first window and the second window, and
wherein the closed space is filled with gas.

3. The substrate processing apparatus of claim 1, wherein a gap between the first window and the second window is smaller than a first thickness of the first window and a second thickness of the second window in the first direction.

4. The substrate processing apparatus of claim 1, wherein the second window is parallel to the first window.

5. The substrate processing apparatus of claim 3, wherein the first thickness of the first window and the second thickness of the second window are same.

6. The substrate processing apparatus of claim 1, further comprising a stage module configured to movably support the chamber in a second direction perpendicular to the first direction.

7. The substrate processing apparatus of claim 6, wherein the stage module comprises:
a first driver configured to move the chamber in the second direction; and
a first guide portion configured to extend in the second direction.

8. The substrate processing apparatus of claim 7, wherein the stage module further comprises:
a second driver configured to move the chamber in a third direction perpendicular to the first direction and the second direction; and
a second guide portion configured to extend in the third direction.

9. The substrate processing apparatus of claim 1, wherein the support portion comprises a heater configured to heat the substrate.

10. The substrate processing apparatus of claim 1, further comprising
a platform provided at a first side of the chamber; and
at least one block provided on the platform.

11. A substrate processing apparatus comprising:
a chamber comprising:
a support portion configured to support a substrate in an internal space of the chamber, and
an opening at a first side of the chamber;
a window portion provided at the opening, the window portion comprising a first window and a second window spaced apart from each other in a first direction;
a laser irradiation device configured to irradiate a laser beam to the substrate through the window portion;
a weight control module to control a position of a center of gravity of the chamber; and
a stage module configured to support the chamber.

12. The substrate processing apparatus of claim 11, wherein the weight control module comprises:
a platform provided on a second side surface of the chamber; and
a block portion on the platform, the block portion configured to have an adjustable weight.

13. The substrate processing apparatus of claim 12, wherein the block portion comprises:
a first block configured to be detachable from the platform; and
a second block configured to be stackable on the first block.

14. The substrate processing apparatus of claim 12, wherein the block portion comprises at least one block comprising:
one or more protrusions on a first side surface of the at least one block, and
one or more grooves corresponding to a shape of the one or more protrusions on a second side surface of the at least one block.

15. The substrate processing apparatus of claim 12, wherein the block portion comprises at least one block comprising a fastening hole extending from a first surface of the at least one block to a second surface of the at least one block, the at least one block being fixed to the platform through a fastening member extending through the fastening hole.

16. The substrate processing apparatus of claim 11, wherein the stage module comprises:
a first driver configured to move the chamber in a second direction perpendicular to the first direction; and
a first guide portion configured to extend in the second direction.

17. The substrate processing apparatus of claim 16, wherein the stage module further comprises:
a second driver configured to move the chamber in a third direction perpendicular to the first direction and the second direction; and
a second guide portion configured to extend in the third direction.

18. A substrate processing apparatus comprising:
a chamber comprising:
a support portion configured to support a substrate in an internal space, and
an opening at a first side of the chamber;
a window portion provided at the opening, the window portion comprising a first window and a second window spaced apart from each other in a first direction;
a support portion in the chamber, the support portion configured to support the substrate;
a laser irradiation device configured to irradiate a laser beam to the substrate through the window portion;
a weight control module configured to control a position of a center of gravity of the chamber; and
a stage module configured to movably support the chamber,
wherein the support portion comprises a heater configured to heat the substrate, and wherein the stage module is configured to move the chamber in a second direction perpendicular to the first direction.

19. The substrate processing apparatus of claim 18, wherein a gap between the first window and the second window is smaller than a first thickness of the first window and a second thickness of the second window in the first direction.

20. The substrate processing apparatus of claim 18, wherein the weight control module comprises at least one detachable block.
